(19) United States
(12) Patent Application Publication
(10) Pub. No.: US 2013/0021844 A1
(43) Pub. Date: Jan. 24, 2013

(54) PHASE CHANGE MEMORY WITH DOUBLE WRITE DRIVERS

(71) Applicant: Hong Beom Pyeon, Ottawa (CA)

(72) Inventor: Hong Beom Pyeon, Ottawa (CA)

(73) Assignee: MOSAID TECHNOLOGIES INCORPORATED, Ottawa, ON (CA)

(21) Appl. No.: 13/636,585

(22) PCT Filed: Mar. 30, 2011
(86) PCT No.: PCT/CA2011/000329

§ 371 Date: Sep. 21, 2012

Related U.S. Application Data
(60) Provisional application No. 61/323,396, filed on Apr. 13, 2010.

(30) Foreign Application Priority Data
Mar. 28, 2011 (US) 13073041

(51) Int. Cl. G11C 11/00

(52) U.S. Cl. 365/163; 365/148

(57) ABSTRACT

A Phase Change Memory (PCM) having double write drivers. A PCM apparatus includes a memory array having a bitline with a first end and a second end for accessing a PCM cell coupled to the bitline between the first end and the second end of the bitline, a first write driver and a second write driver coupled to the first end of the bitline and the second end of the bitline respectively for simultaneously supplying current to the PCM cell when writing to the PCM cell, and a sense amplifier coupled to the second end of the bitline for sensing a resistance of the PCM cell when reading from the PCM cell. Embodiments of the present invention provide apparatuses, methods, and systems having reduced writing current requirements.

### CROSS-REFERENCE TO RELATED APPLICATIONS

This application claims priority from U.S. Provisional Patent Application Ser. No. 61/323,396 filed on 13 Apr., 2010 and U.S. Ser. No. 13/073,041 filed Mar. 28, 2011 (Pyeon) for “PHASE CHANGE MEMORY WITH DOUBLE WRITE DRIVERS”, the entire contents of which are incorporated herein by reference.

### FIELD OF THE INVENTION

The present invention relates generally to Phase Change Memory (PCM) and more specifically to a PCM having double write drivers.

### BACKGROUND

Conventional Phase Change Memory (PCM) devices store data using phase change materials, such as chalcogenide, which are capable of stably transitioning between amorphous and crystalline phases. The amorphous and crystalline phases (or states) exhibit different resistance values used to distinguish different logic states of memory cells in the memory devices. In particular, the amorphous phase exhibits a relatively high resistance and the crystalline phase exhibits a relatively low resistance.

At least one type of phase change memory device-PRAM-uses the amorphous state to represent a logical ‘1’ and the crystalline state to represent a logical ‘0’. In a PRAM device, the crystalline state is referred to as a “set state” and the amorphous state is referred to as a “reset state”. Accordingly, a memory cell in a PRAM stores a logical ‘0’ by setting a phase change material in the memory cell to the crystalline state, and the memory cell stores a logical ‘1’ by setting the phase change material to the amorphous state.

The phase change material in a PRAM is converted to the amorphous state by heating the material to a first temperature above a predetermined melting temperature and then quickly cooling the material. The phase change material is converted to the crystalline state by heating the material at a second temperature lower than the melting temperature but above a crystallizing temperature for a sustained period of time. Accordingly, data is programmed to memory cells in a PRAM by converting the phase change material in memory cells of the PRAM between the amorphous and crystalline states using heating and cooling as described above.

The phase change material in a PRAM typically comprises a compound including germanium (Ge), antimony (Sb), and tellurium (Te), i.e., a “GST” compound. The GST compound is well suited for a PRAM because it can quickly transition between the amorphous and crystalline states by heating and cooling. In addition to, or as an alternative for the GST compound, a variety of other compounds can be used in the phase change material. Examples of the other compounds include, but are not limited to, 2-element compounds such as GaSb, InSb, InSe, Sb₂Te₃, and GeTe, 3-element compounds such as GeSbTe, GaSeTe, InSbTe, SnSb₂Te₄, and InSbGe, or 4-element compounds such as AgInSbTe, (GeSn)SbTe, GeSb(SeTe), and Teₙ Ge₁₅Sb₂S₂.

The memory cells in a PRAM are called “phase change memory cells”. A phase change memory cell typically comprises a top electrode, a phase change material layer, a bottom electrode contact, a bottom electrode, and an access transistor. A read operation is performed on the phase change memory cell by measuring the resistance of the phase change material layer, and a program operation is performed on the phase change memory cell by heating and cooling the phase change material layer as described above.

FIG. 1 is a schematic circuit diagram illustrating a conventional Phase Change Memory (PCM) cell with MOS 10 and a conventional diode PCM cell 20. Referring to FIG. 1, memory cell 10 includes a phase change resistance element 11 comprising the GST compound, and a negative metal-oxide semiconductor (NMOS) transistor 12. Phase change resistance element 11 is connected between a bit line BL and NMOS transistor 12, and NMOS transistor 12 is connected between phase change resistance element 11 and ground. In addition, NMOS transistor 12 has a gate connected to a word line WL.

NMOS transistor 12 is turned on in response to a word line voltage applied to word line WL. Where NMOS transistor 12 is turned on, phase change resistance element 11 receives a current through bit line BL.

Referring to FIG. 1, memory cell 20 comprises a phase change resistance element 21 connected to a bitline BL, and a diode 22 connected between phase change resistance element 21 and a wordline WL.

Phase change memory cell 20 is accessed by selecting wordline WL and bitline BL. In order for phase change memory cell 20 to work properly, wordline WL preferably has a lower voltage level than bitline BL when wordline WL is selected so that current can flow through phase change resistance element 21. Diode 22 is forward biased so that if wordline WL has a higher voltage than bitline BL, no current flows through phase change resistance element 21. To ensure that wordline WL has a lower voltage level than bitline BL, wordline WL is generally connected to ground when selected.

In FIG. 1, phase change resistance elements 11 and 21 can alternatively be broadly referred to as “memory elements” and NMOS transistor 12 and diode 22 can alternatively be broadly referred to as “select elements”.

The operation of phase change memory cells 10 and 20 is described below with reference to FIG. 2. In particular, FIG. 2 is a graph illustrating temperature characteristics of phase change resistance elements 11 and 21 during programming operations of memory cells 10 and 20. In FIG. 2, a reference numeral 1 denotes temperature characteristics of phase change resistance elements 11 and during a transition to the amorphous state, and a reference numeral 2 denotes temperature characteristics of phase change resistance elements 11 and 21 during a transition to the crystalline state.

Referring to FIG. 2, in a transition to the amorphous state, a current is applied to the GST compound in phase change resistance elements 11 and 21 for a duration T1 to increase the temperature of the GST compound above a melting temperature Tm. After duration T1, the temperature of the GST compound is rapidly decreased, or “quenched”, and the GST compound assumes the amorphous state. On the other hand, in a transition to the crystalline state, a current is applied to the GST compound in phase change resistance elements 11 and 21 for an interval T2 (T2>T1) to increase the temperature of the GST compound above a crystallization temperature Tx (Tx 2, the GST compound is slowly cooled down below the crystallization temperature so that it assumes the crystalline state.

A phase change memory device typically comprises a plurality of phase change memory cells arranged in a memory cell array. Within the memory cell array, each of the memory cells is typically connected to a corresponding bit line and a corresponding word line. For example, the memory cell array may comprise bit lines arranged in columns and word lines arranged in rows, with a phase change memory cell located near each intersection between a column and a row.

Typically, a row of phase change memory cells connected to a particular word line are selected by applying an appropriate voltage level to the particular word line. For example, to select a row of phase change memory cells similar to phase change memory cell 10 illustrated in the left side of FIG. 1, a relatively high voltage level is applied to a corresponding word line WL to turn on NMOS transistor 12. Alternatively, to select a row of phase change memory cells similar to phase change memory cell 20 illustrated in the right side of FIG. 1, a relatively low voltage level is applied to a corresponding word line WL so that current can flow through diode 22.

The SLC (single level) cell with PCM has a lot of sensing margin between logic ‘1’ (amorphous, reset state) and logic ‘0’ ('crystalline, set state) due to the resistive difference almost 10 to 100 times. However, in case of MLC (Multiple Level Cell), the distinguishing difference between two logic states would not be continued. As well, the Phase change memory density has increased drastically so that the near cell and far cell writing characteristics is one of issues to be resolved.

In U.S. Pat. No. 7,110,286, “PHASE-CHANGE MEMORY DEVICE AND METHOD OF WRITING A PHASE-CHANGE MEMORY DEVICE”, to Choi et al., issued Sep. 19, 2006 (hereinafter, Choi) and incorporated herein by reference, there is disclosed a different pulse control depending on the row addresses to compensate the cell resistance variation induced by a bit line parasitic resistive factor. Choi can resolve the cell set and reset resistance variation, but it needs more complicated control with row address inputs. Also, its variation difference is changed depending on the process condition and process technologies.

Accordingly, there is a need for the development of an improved apparatus, method, and system using PCM as well as non-volatile memory devices and systems utilizing such improved PCM.

### SUMMARY

It is an object of the present invention to provide an apparatus, method, and system using Phase Change Memory (PCM) having reduced effects of high write current.

According to one aspect of the invention the is provided an apparatus including a memory array having a bitline with a first end and a second end for accessing a PCM cell coupled to the bitline between the first end and the second end of the bitline, a first write driver and a second write driver coupled to the first end of the bitline and the second end of the bitline respectively for simultaneously supplying current to the PCM cell when writing to the PCM cell; and a sense amplifier coupled to the second end of the bitline for sensing a resistance of the PCM cell when reading from the PCM cell.

Beneficially, the first write driver and the second write driver are coupled to the first end of the bitline and second end of the bitline through a first column selector and a second column selector respectively.

Beneficially, the memory array comprises a wordline coupled to the PCM cell for selecting the PCM cell.

Alternatively, the wordline is coupled to the PCM cell by an insulated-gate field effect transistor (IGFET) or a diode.

Advantageously, the PCM cell is a Multiple Level Cell (MLC).

According to another aspect of the invention there is provided a method of writing data to a PCM cell including supplying current to the PCM cell simultaneously from a first write driver and a second write driver coupled to a first end of a bitline and a second end of the bitline respectively.

Beneficially, the method includes selecting the PCM cell using a wordline.

Beneficially, supplying current to the PCM cell simultaneously from a first write driver and a second write driver includes supplying current to the PCM cell simultaneously from a first write driver through a first column selector and a second write driver through a second column selector

According to yet another aspect of the invention there is provided a system including a Phase Change Memory (PCM) apparatus having a memory array including a bitline having a first end and a second end for accessing a PCM cell coupled to the bitline between the first end and the second end of the bitline, a first write driver and a second write driver coupled to the first end of the bitline and the second end of the bitline respectively for simultaneously supplying current to the PCM cell when writing to the PCM cell; and a sense amplifier coupled to the second end of the bitline for sensing a resistance of the PCM cell when reading from the PCM cell.

Preferably, the first write driver and the second write driver are coupled to the first end of the bitline and second end of the bitline through a first column selector and a second column selector respectively.

Beneficially, the memory array comprises a wordline coupled to the PCM cell for selecting the PCM cell.

Optionally, the wordline is coupled to the PCM cell by an insulated-gate field effect transistor (IGFET) or a diode.

Preferably, the PCM cell is a Multiple Level Cell (MLC).

Thus improved apparatuses, methods, and systems have been provided.

### BRIEF DESCRIPTION OF THE DRAWINGS

Further features and advantages of the present invention will become apparent from the following detailed description, taken in combination with the appended drawings, in which:

FIG. 1 is a schematic diagram of a conventional NMOS switch PCM (Phase Change Memory) cell and a conventional diode switch PCM cell;

FIG. 2 is a graph of temperature change during a set and a reset operation of a conventional PCM cell;

FIG. 3 is a schematic diagram of circuits in a cell array of a conventional PCM device;

FIG. 4 is a schematic diagram of an equivalent circuit of a bit line shown in FIG. 3;

FIGS. 5A and 5B are distribution diagrams of data in multilevel cells in PCM devices;

FIG. 6 is a block diagram of a first embodiment of a PCM device in accordance with an example embodiment of the invention;

FIG. 7A is a schematic diagram of circuits in a cell array of the PCM device shown in FIG. 6;

FIG. 7B is a schematic diagram of an equivalent circuit of a bit line shown in FIG. 7A;

FIGS. 8A and 8B are schematic diagrams of equivalent circuits for voltage sensing and current sensing respectively;

FIG. 9 is a block diagram of a second embodiment of a PCM device in accordance with an example embodiment of the invention;

FIG. 10 is a block diagram of a third embodiment of a PCM device in accordance with an example embodiment of the invention; and

FIGS. 11A to 11C are diagrams of electric devices including the memories shown in FIGS. 6, 9, and 10 respectively.

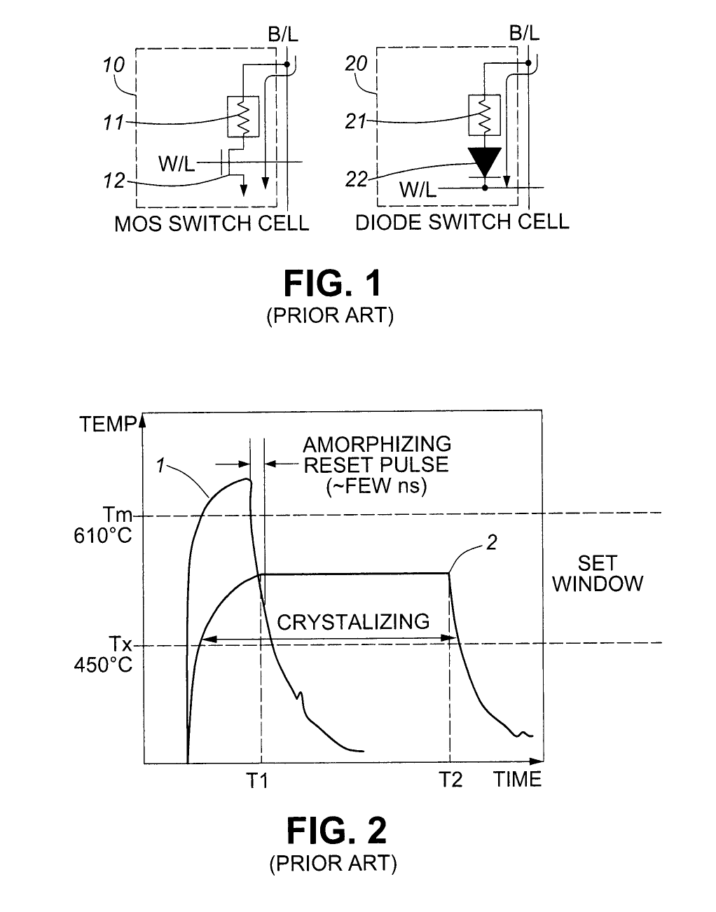

It will be noted that throughout the appended drawings, like features are identified by like reference numerals.

### DETAILED DESCRIPTION OF EMBODIMENTS

As described herein above, the write current variation caused by distance from the write driver to a destination cell affects cell resistance distributions of Phase Change Memory (PCM) cells and especially MLC (Multiple Level Cell) PCM cells.

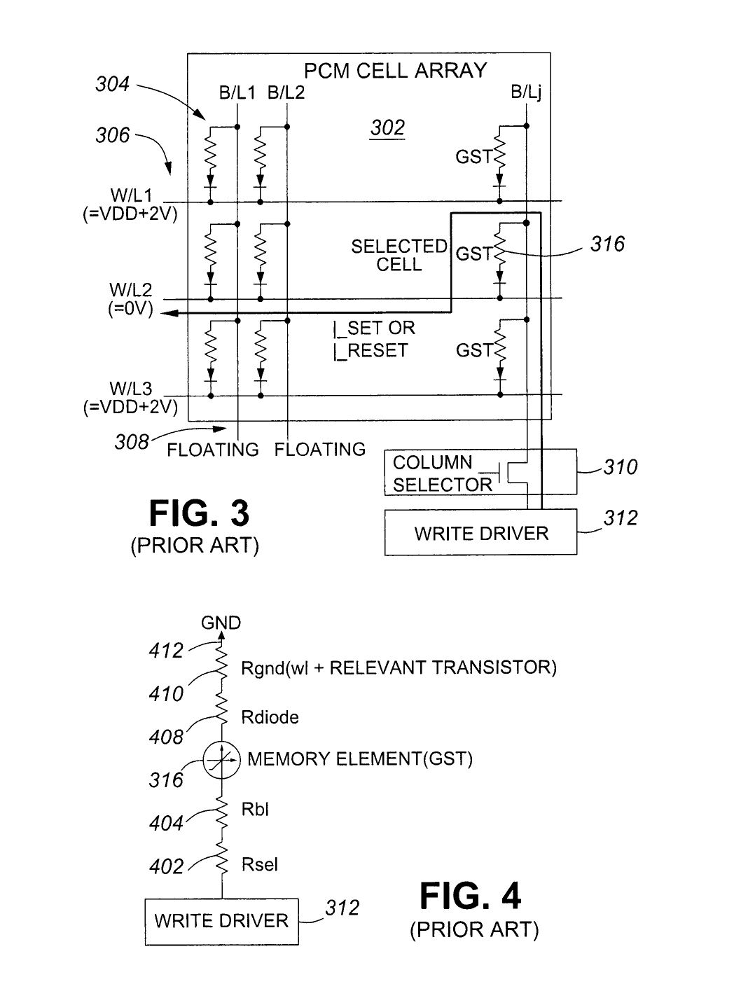

FIG. 3 is a schematic diagram of circuits in a cell array 302 of a conventional PCM device. The array includes a plurality of PCM cells 304 arranged in rows selectable by wordlines 306 and columns selectable by bitlines 308 and column selectors 310. The arrow 314 indicates a path of write current taken from a write driver 312 through a selected cell 316 to ground.

Referring to FIG. 4, there is shown schematically four representative resistive factors from the write driver 312 to memory cell ground 412, there are:
Rₛₑₗ Column selector transistor channel resistance 402
R_{bl} Parasitic bit line resistance 404
R_{diode}: diode forward-bias resistance 408
R_{gnd}: Word line resistance (junction resistance)+relevant MOS transistor channel resistance 410.

Unlike a DRAM bit line which has parasitic capacitance as dominant power consumption factor and performance degradation, the phase change memory needs very high write current flowing through the direct current path between V_{DD} and Vₛₛ. Therefore, the resistive factor on bit lines is more important than the capacitive one. In order to reduce the parasitic resistance, one can increase the width or height of bit line. However, it causes cell size due to the wider bit line and low cell yield by topological difficulty.

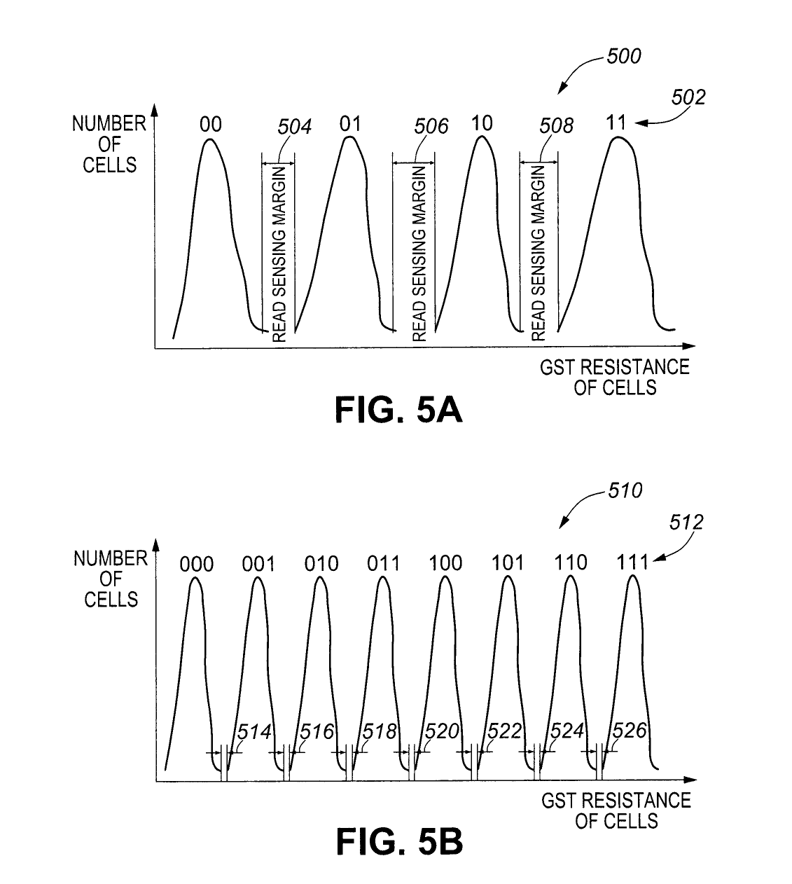

Referring to FIG. 5A, there is shown a data distribution diagram 500 of a 2 bits/cell multi-level cell (MLC) PCM device. MLC implementation demands more precise control of cell resistance distribution 501 for each logic value 502 to ensure read operation margins 504, 506, 508 among bit definitions. When more bits are assigned into the single cell, as in FIG. 5B where there is shown a data distribution diagram 510 of a 3 bits/cell MLC PCM device for each logic value 512, the read operation margins 514, 516, 518, 520, 522, 524, 526 are reduced.

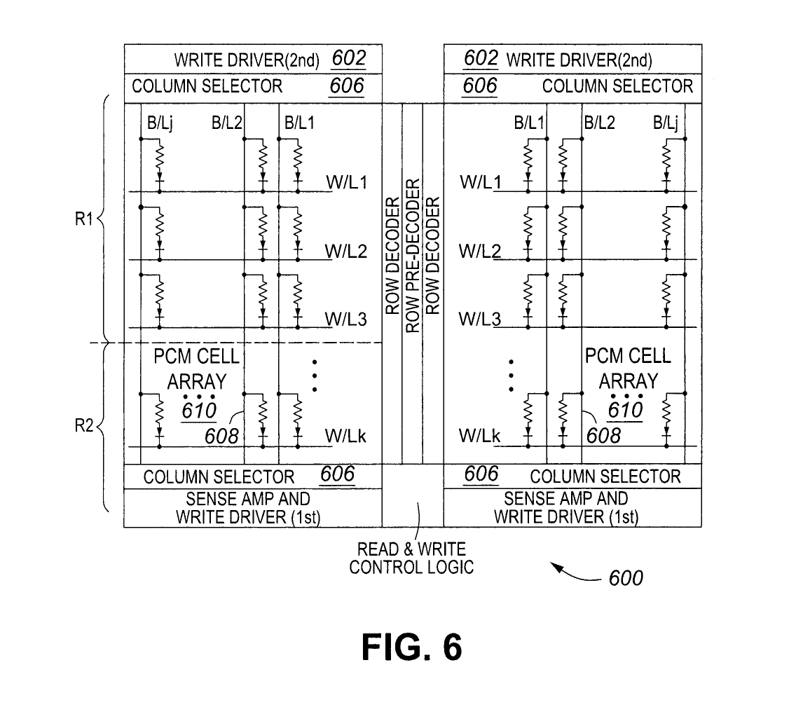

Referring to FIG. 6, there is shown a block diagram of a PCM memory 600 including a first embodiment in accordance with the present invention that provides two physically separated write drivers 602, 604 (also referred to herein as double write drivers) at a top 602 and a bottom 604 end of a PCM memory cell array 610. Preferably both write drivers on the top 602 and bottom 604 sides drive simultaneously write current to a same selected cell. The top and bottom write (also referred to herein as first and second write drivers respectively) drivers 602, 604 are connected or coupled electrically through the column selector 606 to the same bit line 608. Note that the terms “top” and “bottom” are used herein for convenience and clarity when referring to the figures. The memory 600 may be oriented in any position and be within the scope of the invention.

conventional row decoder 614 and row pre-decoder 614 control selection of the wordlines 306. Read/Write control logic 612 controls operation of the row decoders 614, row pre-decoders 616, column selectors 606, sense amps 604 and write drivers 602

Placement of double write drivers 602,604 according to an embodiment of the invention provides advantages of: reduction of parasitic bit line resistance by maximum 50% of Rbl, that is, the middle of phase change memory cell has a distal position from the write drivers; and column selector channel resistance effect can be suppressed by equivalent write driver current from top and bottom sides write drivers 602, 604.

The read sense amplifier 604 is preferably placed at one end of the bit line 608 unlike the double write drivers 602,604. Since the read sensing is preferably not done at both sides at the same time and the read operation does not need separate control. Other preferred embodiments will be disclosed herein below showing a location of the read sense amplifier.

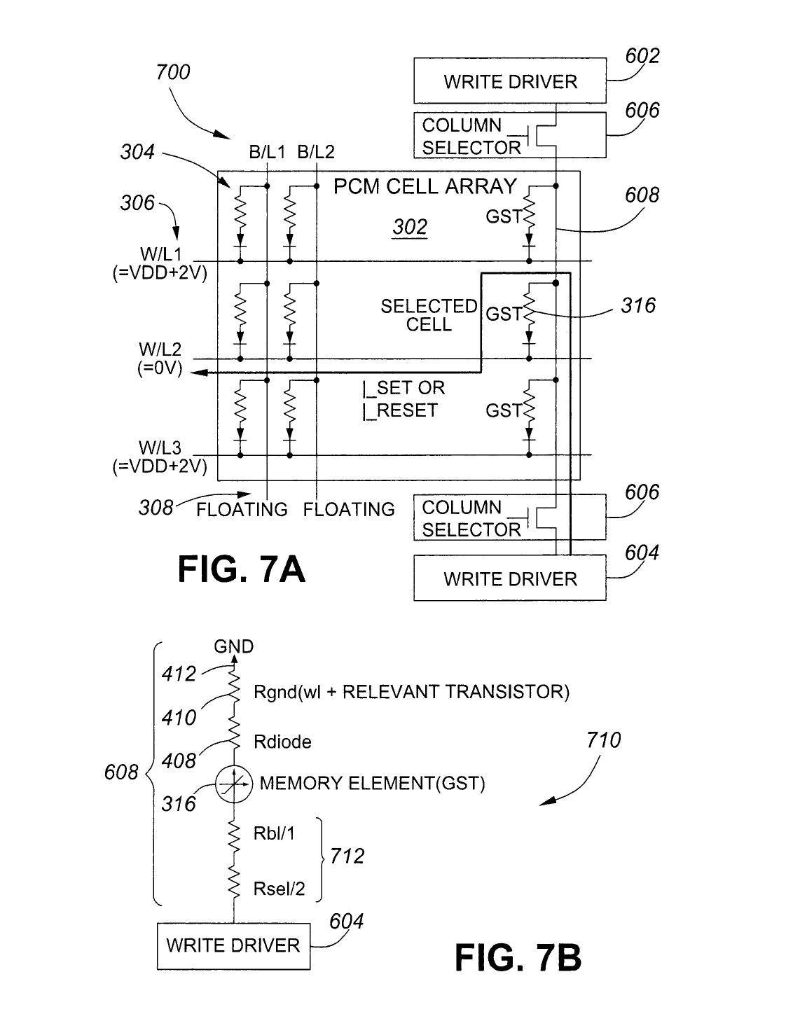

Embodiments of the present invention effectively reduce the parasitic bit line resistance and selector transistor channel resistance. FIG. 7A shows the reduction effect of two resistive factors on the bit line 608. FIG. 7B is a schematic diagram of an equivalent circuit 710 of a bit line 608 shown in FIG. 7A for a worst case cell, that is the cell half way between the double write drivers 602, 604. Note the halving of the bitline resistance and column selector channel resistance 712.

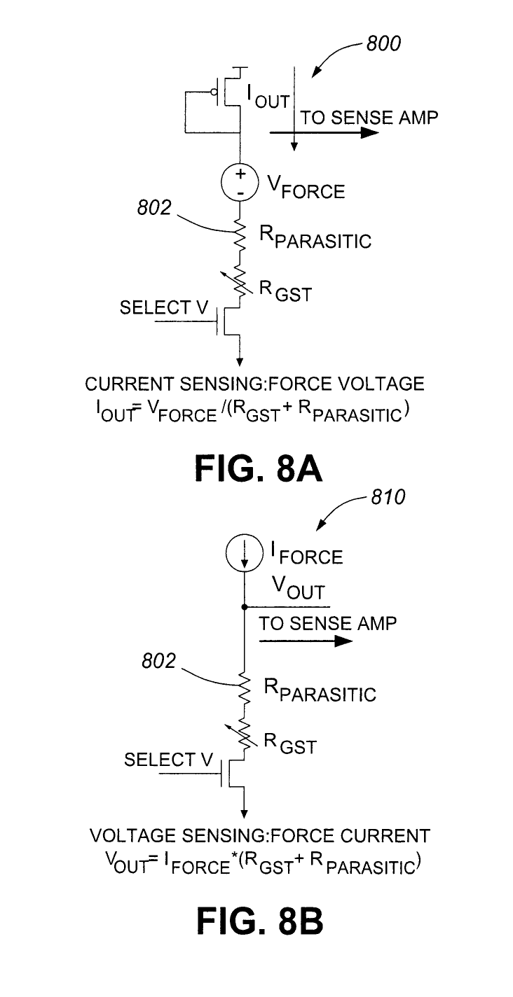

Referring to FIGS. 8A and 8B, the current sensing method 800 is affected by R_{parasitic} 802 (bit line parasitic resistance); the voltage sensing method 810 is not affected by R_{parasitic} 802. Their relationships are derived from basic equations of sensing values.

### Current Sensing 800:

Iₒₙₑ=V_{force}/(R_{GST}_{_{—}}ᵣₑₛₑₜ+R_{parasitic})

I_{zero}=V_{force}/(R_{GST}_{_{—}}ₛₑₜ+R_{parasitic})

I_{zero}−Iₒₙₑ (Current sensing margin)=V*(R_{GST}_{_{—}}ᵣₑₛₑₜ−R_{GST}_{_{—}}ₛₑₜ)/(R_{GST}_{_{—}}ᵣₑₛₑₜ*R_{GST}_{_{—}}ₛₑₜ+R²_{parasitic}+R_{parasitic}(R_{GST}_{_{—}}ᵣₑₛₑₜ+R_{GST}_{_{—}}ₛₑₜ

### Voltage Sensing 810:

Vₒₙₑ=I_{force}*(R_{GST}_{_{—}}ᵣₑₛₑₜ+R_{parasitic})

V_{zero}=I_{force}*(R_{GST}_{_{—}}ₛₑₜ+R_{parasitic})

Vₒₙₑ−V_{zero} (Voltage sensing margin)=I_{force}*(R_{GST}_{_{—}}ᵣₑₛₑₜ−R_{GST}_{_{—}}ₛₑₜ); R_{parasitic} is not included.

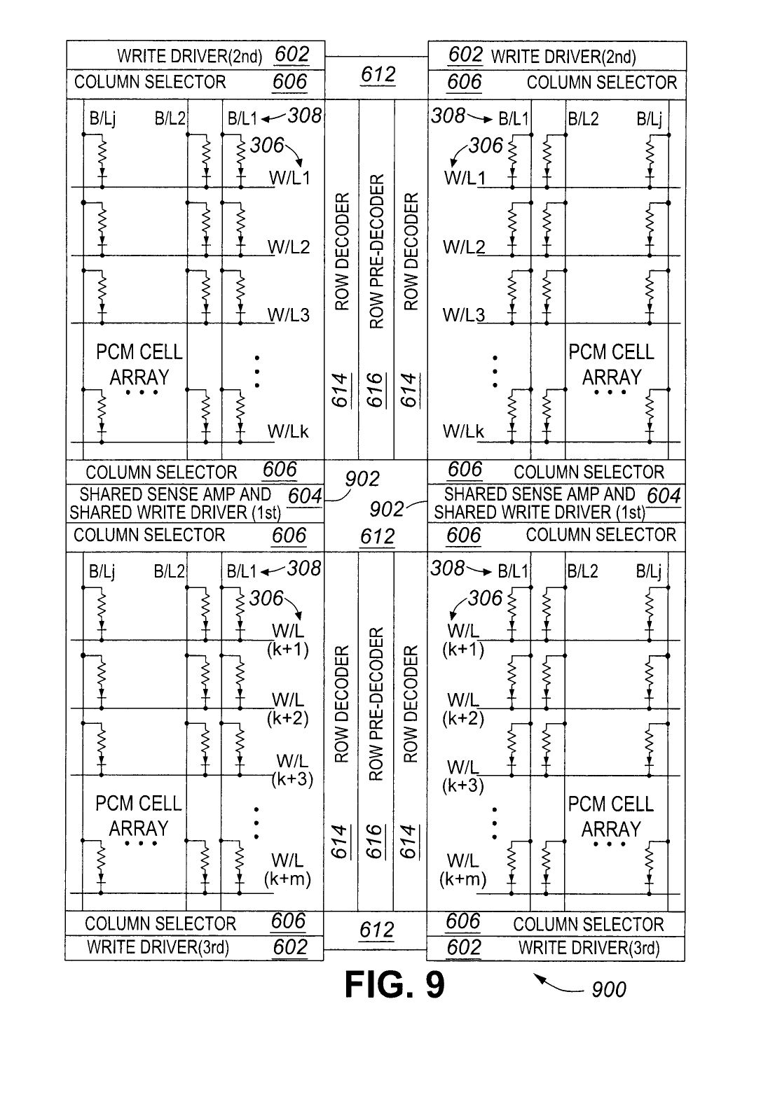

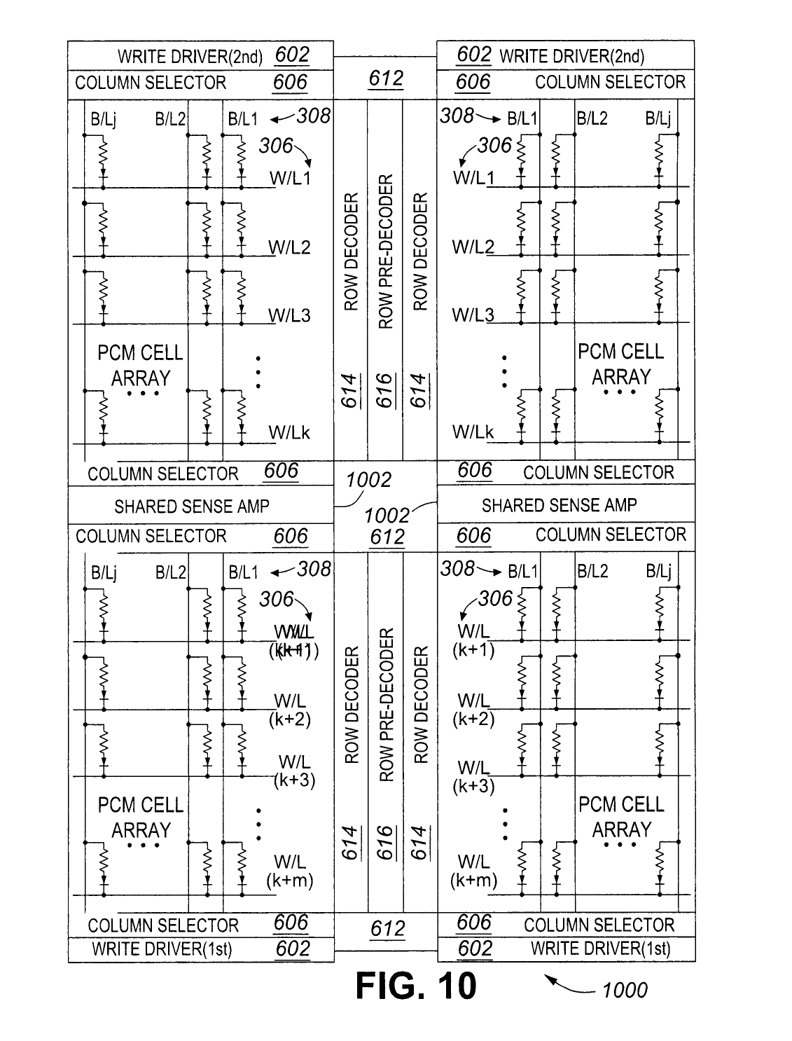

Other embodiments of the present invention can provide smaller chip size in case of multiple memory arrays. The shared sense amplifier and write drivers can be placed into the center of memory array. For example, referring to FIG. 9, there is shown a block diagram 900 of a second embodiment of the present invention. The sense amplifiers and write drivers 902 are shared between top and bottom memory arrays or more generally between adjacent memory arrays. In a third embodiment shown in FIG. 10, only the sense amplifiers 1002 are shared between top and bottom memory arrays.

Advantageously, embodiments of the present invention provide a double write driver configuration with two-side placement (top and bottom of memory array) for same bit line. Only one side of write driver has read sense amplifier (top or bottom).

Embodiments of the present invention also provide better read operation sensing margin along with narrow cell resistance distribution for each logic state.

The center of memory array has the read sense amplifier while the top and bottom sides of memory array have write drivers.

Both sides of write drivers are simultaneously activated for the same bit line.

Any type of phase change memory (NMOS selector, bipolar, and diode) can be applied to implement embodiments of the present invention.

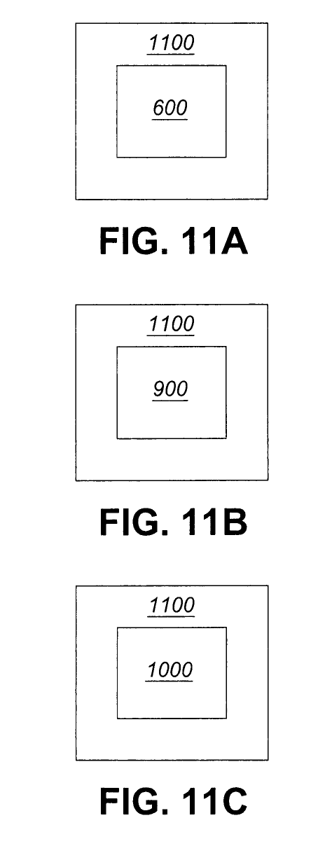

As described herein above the memory systems shown in FIGS. 6, 9, and 10 may also be embedded, as shown in FIGS. 11A, 11B, and 11C respectively, in an electric device 1100. The electric device 1100 may be, for example, a memory stick, a solid state disk (SSD), a laptop computer, a desktop computer, a personal digital assistant (PDA), audio player, or the like where the advantages of embodiments of the present invention are especially beneficial.

The embodiments of the invention described above are intended to be exemplary only. The scope of the invention is therefore intended to be limited solely by the scope of the appended claims.

What is claimed is:

1. An apparatus comprising:
a memory array including a bitline having a first end and a second end for accessing a Phase Change Memory (PCM) cell coupled to the bitline between the first end and the second end of the bitline; and
a first write driver and a second write driver coupled to the first end of the bitline and the second end of the bitline respectively for simultaneously supplying current to the PCM cell during writing to the PCM cell

2. The apparatus as claimed in claim 1 further comprising a sense amplifier coupled to the first end or the second end of the bitline for sensing a resistance of the PCM cell during reading from the PCM cell.

3. The apparatus as claimed in claim 1 further comprising a first column selector and a second column selector for coupling the first write driver and the second write driver to the first end of the bitline and second end of the bitline respectively.

4. The apparatus as claimed in claim 1 further comprising a wordline coupled to the PCM cell for selecting the PCM cell.

5. The apparatus as claimed in claim 4 further comprising an insulated-gate field effect transistor (IGFET) for coupling the wordline to the PCM cell.

6. The apparatus as claimed in claim 4 further comprising a diode for coupling the wordline to the PCM cell.

7. The apparatus as claimed in claim 1 wherein the PCM cell is a Multiple Level Cell (MLC).

8. The apparatus as claimed in claim 1 wherein the first write driver is shared between the memory array and an adjacent memory array.

9. A method of writing data to a Phase Change Memory (PCM) cell comprising:
selecting the PCM cell; and
supplying current to the selected PCM cell simultaneously from a first write driver and a second write driver coupled to a first end of a bitline and a second end of the bitline respectively.

10. The method as claimed in claim 9 wherein selecting the PCM cell comprises selecting the PCM cell using a wordline.

11. The method as claimed in claim 9 wherein supplying current to the PCM cell simultaneously from a first write driver and a second write driver comprises:
supplying current to the PCM cell simultaneously from a first write driver through a first column selector and a second write driver through a second column selector.

12. A system comprising:
a Phase Change Memory (PCM) apparatus having a memory array;
the memory array including a bitline having a first end and a second end for accessing a PCM cell coupled to the bitline between the first end and the second end of the bitline; and
a first write driver and a second write driver coupled to the first end of the bitline and the second end of the bitline respectively for simultaneously supplying current to the PCM cell during writing to the PCM cell.

13. The system as claimed in claim 12 further comprising a sense amplifier coupled to the first end or the second end of the bitline for sensing a resistance of the PCM cell during reading from the PCM cell.

14. The system as claimed in claim 12 further comprising a first column selector and a second column selector for coupling the first write driver and the second write driver to the first end of the bitline and second end of the bitline respectively.

15. The system as claimed in claim 12 further comprising a wordline coupled to the PCM cell for selecting the PCM cell.

16. The system as claimed in claim 15 further comprising an insulated-gate field effect transistor (IGFET) for coupling the wordline to the PCM cell.

17. The system as claimed in claim 15 further comprising a diode for coupling the wordline to the PCM cell.

18. The system as claimed in claim 12 wherein the PCM cell is a Multiple Level Cell (MLC).

19. The system as claimed in claim 12 wherein the first write driver is shared between the memory array and an adjacent memory array.
